(19) United States
(12) Patent Application Publication
(10) Pub. No.: US 2021/0225903 A1
(43) Pub. Date: Jul. 22, 2021

(54) ETCHING METHOD, MANUFACTURING METHOD OF THIN FILM TRANSISTOR, PROCESS DEVICE AND DISPLAY DEVICE

(71) Applicants: BOE Technology Group Co., Ltd., Beijing (CN); Hefei Xinsheng Optoelectronics Technology Co., Ltd., Hefei (CN)

(72) Inventors: Shengping Du, Beijing (CN); Tongshang Su, Beijing (CN); Zhengfeng Huang, Beijing (CN); Yu Yang, Beijing (CN); Wang Zhang, Beijing (CN); Lei Wang, Beijing (CN); Yun Ma, Beijing (CN); Lihua Liu, Beijing (CN); Guangdong Liu, Beijing (CN); Wen Guo, Beijing (CN)

(21) Appl. No.: 16/305,451

(22) PCT Filed: Apr. 27, 2018
(86) PCT No.: PCT/CN2018/084960

§ 371 Date: Nov. 29, 2018

(30) Foreign Application Priority Data
Aug. 31, 2017 (CN) 201710771004.3

(51) Int. Cl. H01L 27/12

(52) U.S. Cl. CPC H01L 27/1288; H01L 27/1266

(57) ABSTRACT

The present disclosure provides an etching method, a manufacturing method of a thin film transistor, a process device and a display device. The etching method includes: forming a patterned photoresist layer on the surface of a material to be etched, the patterned photoresist layer exposing an area to be etched on the surface of the material to be etched; curing the photoresist layer by adopting a plasma process; and etching the material to be etched by adopting an etching solution corresponding to the material to be etched. The present disclosure can help to solve the problem of undercutting and improve the product yield and product performances.

This application claims priority to Chinese Patent Application No. 201710771004.3, filed with the China National Intellectual Property Administration on Aug. 31, 2017 and titled “ETCHING METHOD, PROCESS DEVICE, THIN FILM TRANSISTOR, AND MANUFACTURING METHOD THEREOF”, the entire contents of which are incorporated herein by reference.

### TECHNICAL FIELD

The present disclosure relates to the field of semiconductor manufacturing, and in particular, to an etching method, a manufacturing method of a thin film transistor, a process device and a display device.

### BACKGROUND

Etching is a semiconductor manufacturing process, and it is an important step in the microelectronic manufacturing process and the micro-nano manufacturing process. Etching refers to a process of peeling and removing materials by a manner such as using a solution, reactive ions or a mechanical means. At present, etching mainly includes wet etching (WE) and dry etching (DE).

### SUMMARY

The present disclosure relates to an etching method, a manufacturing method of a thin film transistor, a process device and a display device.

In a first aspect, the present disclosure provides an etching method, comprising:

forming a patterned photoresist layer on the surface of a material to be etched, the patterned photoresist layer exposing an area to be etched on the surface of the material to be etched;

curing the photoresist layer by adopting a plasma process; and

etching the material to be etched by adopting an etching solution corresponding to the material to be etched.

In a possible implementation, curing the photoresist layer by adopting a plasma process comprises:

curing the photoresist layer by adopting a reactive ion etching process.

In a possible implementation, the material forming the photoresist layer is an organic polymer material, and the plasma used in the plasma process is generated by ionizing a mixture of carbon tetrafluoride and oxygen.

In a possible implementation, the material forming the photoresist layer is a positive photoresist of the type PR1-1000A, and the plasma used in the plasma process is generated by ionizing a mixture of carbon tetrafluoride and oxygen.

In a possible implementation, after etching the material to be etched by adopting an etching solution corresponding to the material to be etched, the method further comprises:

performing ashing treatment on the cured photoresist layer by adopting plasma capable of oxidizing the photoresist layer.

In a possible implementation, performing ashing treatment on the cured photoresist layer by adopting plasma capable of oxidizing the photoresist layer comprises:

performing the ashing treatment on the photoresist layer by adopting a reactive ion etching process.

In a possible implementation, the material forming the photoresist layer is an organic polymer material, and the plasma capable of oxidizing the photoresist layer is generated by ionizing a mixture of carbon tetrafluoride and oxygen.

In a second aspect, the present disclosure further provides a manufacturing method of a thin film transistor, comprising:

forming a first metal layer to be etched on a substrate, the first metal layer comprising a conductive layer and protective layers on both sides of the conductive layer; and

etching the first metal layer by adopting any one of the etching methods described above, to form a pattern comprising a gate electrode in the first metal layer.

In a possible implementation, the manufacturing method of a thin film transistor further comprises:

forming a first insulating layer on the first metal layer;

forming a pattern comprising an active layer on the first insulating layer;

forming a second metal layer to be etched on the first insulating layer and the active layer;

etching the second metal layer by adopting any one of the etching methods described above, to form a pattern comprising a source electrode and a drain electrode in the second metal layer; and

forming a second insulating layer on the active layer and the second metal layer.

In a possible implementation, the conductive layer is made of copper or a copper-containing alloy, and the protective layers are made of molybdenum or a molybdenum-containing alloy.

In a third aspect, the present disclosure further provides a process device adopted by any one of the etching methods described above, comprising:

a first mechanism configured to form a patterned photoresist layer on the surface of a material to be etched on a substrate, the patterned photoresist layer exposing an area to be etched on the surface of the material to be etched;

a second mechanism, connected to the first mechanism, and configured to receive the substrate processed by the first mechanism, and cure the photoresist layer by adopting a plasma process; and

a third mechanism connected to the second mechanism and configured to receive the substrate processed by the second mechanism and to etch the material to be etched in the area to be etched by adopting an etching solution corresponding to the material to be etched.

In a possible implementation, the second mechanism is further configured to receive the substrate processed by the first mechanism and cure the photoresist layer by adopting a reactive ion etching process.

In a possible implementation, the material forming the photoresist layer is an organic polymer material, and the plasma used in the plasma process is generated by ionizing a mixture of carbon tetrafluoride and oxygen.

In a possible implementation, the process device further comprises:

a fourth mechanism, connected to the third mechanism and configured to receive the substrate processed by the third mechanism, and perform ashing treatment on the cured photoresist layer by adopting plasma capable of oxidizing the photoresist layer.

In a possible implementation, the fourth mechanism is further configured to receive the substrate processed by the third mechanism, and perform ashing treatment on the cured photoresist layer by adopting a reactive ion etching process.

In a possible implementation, the material forming the photoresist layer is an organic polymer material, and the plasma capable of oxidizing the photoresist layer is generated by ionizing a mixture of carbon tetrafluoride and oxygen.

In a fourth aspect, the present disclosure further provides a display device, comprising a thin film transistor obtained by any one of the manufacturing methods described above.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description show merely some embodiments of the present disclosure, and all reasonable variations of these drawings shall fall within the protection scope of the present disclosure.

FIG. 1 is a flow chart of an etching method provided according to an embodiment of the present disclosure;

FIG. 2 is a flow chart of an manufacturing method of a thin film transistor provided according to an embodiment of the present disclosure;

FIG. 3 to FIG. 10 are schematic diagrams of structures of sections in various phases during the manufacturing process of a thin film transistor provided according to an embodiment of the present disclosure;

FIG. 11 is a flow chart of an manufacturing method of an array substrate provided according to an embodiment of the present disclosure;

FIG. 12 is a schematic diagram of a structure of a process device according to an embodiment of the present disclosure; and

FIG. 13 is a schematic diagram of a structure of a display device according to an embodiment of the present disclosure.

### DETAILED DESCRIPTION

To clearly present the principles and benefits of the present disclosure, the embodiments of the present disclosure will be described in details with reference to the enclosed drawings. Obviously, the embodiments presented here are only some but not all embodiments of present disclosure. All other embodiments obtained by those skilled in the art based on the presented embodiments of present disclosure are protected by present disclosure, unless those embodiments are obtained by their creative works. Unless otherwise defined, technical terms or scientific terms used in the present disclosure should have the ordinary meaning understood by those of ordinary skill in the art. The words “first”, “second” and similar terms used in the present disclosure do not denote any order, quantity, or importance, and are merely used to distinguish different components. The word “comprise” or similar terms mean that elements or objects appearing before the term cover the listed elements or objects and its equivalents appearing after the term while other elements or objects are not excluded. The word “connected” or “coupled” and similar terms are not limited to physical or mechanical connections, and may include electrical connection and the connection may be direct or indirect.

In the related art, when the patterning processing of a material is performed by etching, the photoresist easily forms a specified pattern by illumination, and thus can be used to cover the surface of a part of the material, so that the etching is only performed on the surface of the uncovered material. Therefore, the patterning of the material is achieved by designing the photoresist pattern. However, due to the poor adhesivity of the photoresist on some materials, when these materials are etched, tiny gaps will be generated at the interface between the photoresist and the material to be etched, so that etchant can very easily penetrate through these tiny gaps and cause undercutting (also called as “transverse undercutting” or “lateral undercutting”).

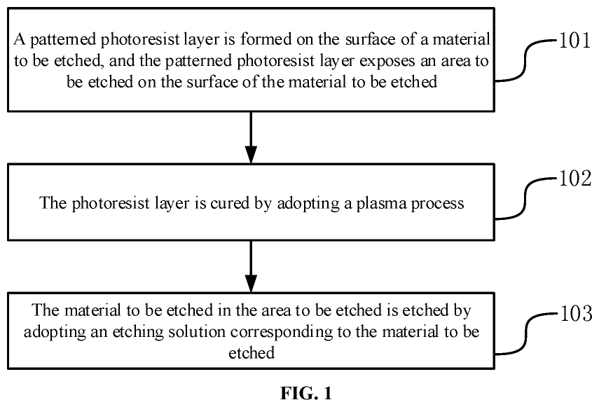

In view of the above problems, FIG. 1 is a flow chart of an etching method provided by an embodiment of the present disclosure. Referring to FIG. 1, the etching method comprises the following steps.

In step 101, a patterned photoresist layer is formed on the surface of a material to be etched, and the patterned photoresist layer exposes an area to be etched on the surface of the material to be etched.

In step 102, the photoresist layer is cured by adopting a plasma process.

In step 103, the material to be etched in the area to be etched is etched by adopting an etching solution corresponding to the material to be etched.

It should be understood that the etching method according to the present embodiment can be applied to any application scenario where the etching is required to be performed in a designated area on the surface of a material. The material is the material to be etched, and the designated area is the area to be etched on the surface of the material to be etched. For example, in the manufacturing process of an array substrate, in the application scenario that after the step of cleaning a glass substrate and the step of depositing the metal film layer for forming a gate electrode conductive layer on the glass substrate, the area to be etched on the surface of the metal film layer to be etched needs to be etched to obtain a pre-designed pattern of the gate electrode conductive layer (for example, the pattern comprising a gate line, a gate electrode, a common electrode wire, etc.), the etching method according to the present embodiment can be applied. For another example, in the manufacturing process of an organic light-emitting diode (OLED) device, the etching method according to the present embodiment can be applied to any one or more etching steps of the patterning process. Considering process simplification and cost saving, the etching method according to the present embodiment can be applied only to the etching step in which the undercutting phenomenon is relatively easy to occur. Of course, the optional application scenario of the present embodiment is not limited to the above examples.

In the above step 101, the patterned photoresist layer may be manufactured based on a full-surface photoresist layer by the processes which are in accordance with the distribution position of the area to be etched, such as exposure and development etc. In the process, for example, a mask having a pattern corresponding to the distribution position of the area to be etched may be used. For the etching method according to the present embodiment, the patterning manner of the photoresist layer does not affect the solution to the problem of undercutting. Therefore, the exposure and development on the positive photoresist, the exposure and development on the negative photoresist, or the patterning of the photoresist layer by a half-tone mask (HTM) process or other manners is possible to apply in the etching method according to the present embodiment. It should be noted that the material forming the photoresist layer may be selected from any photo resistive (PR) material in a possible range. Moreover, in the situations where the undercutting is prone to occur since the adhesivity between the material for forming the photoresist layer and the material to be etched is poor (for example, the minimum value of energy required to separate the two from each other is lower than a predetermined threshold), the etching method according to the present embodiment is especially suitable.

In the above step 102, the process of curing the photoresist layer by the plasma process actually corresponds to a process which can be observed in the field of dry etching and is not conducive to the normal process.

The dry etching mainly utilizes physical and chemical reactions between the plasma and the material to be etched to achieve etching. But in such process, the photoresist for protecting the areas other than the area to be etched from being etched interacts with the plasma. As the photoresist interacts with the plasma, the photoresist is easily denatured and solidified, the internal molecular alignment becomes more compact, and the texture becomes harder and even is difficult to remove by a developing solution. In order to carry out the subsequent process, the photoresist must be peeled off at first. At this point, the removal by the developing solution has to be discarded, and other more complex and high-cost measures are adopted to peel the photoresist. Moreover, according to the difference of the selected measures, there may be the cases where the photoresist is not completely peeled off or the structural surface under the photoresist is damaged, which affects the quality of the product.

On such basis, the technicians of dry etching will try to prevent the photoresist from being cured under the exposure of the plasma during the etching process, and the photoresist is peeled in a simple removal manner by the developing solution as much as possible, so that the process of the peeling the cured photoresist, which affects the quality of the product, is avoided.

However, the inventors of the present application found in practice that if the cured photoresist is used as a mask for wet etching, the occurrence of the undercutting phenomenon will be significantly reduced. That is, in turn, the phenomenon that the photoresist is cured under the exposure of the plasma, which is generally not conducive to the dry etching process, is used to improve the etching effect of the wet etching. In the field, in the application scenarios where the dry etching has been selected, the etchants other than plasma are generally not considered, and the wet etching which has the advantages of simplicity and convenience, rapidness and low cost will not bring the relatively complex and high-cost plasma treatment into to the procedure.

Thus, the combination of the photoresist and the plasma which are known to have the curing phenomenon can be applied to the etching method according to the present embodiment. For example, the component of the plasma which is known to generate the curing action on certain photoresist material can be applied to the above step 102 to complete the curing process of the photoresist layer. Exemplarily, for the photoresist layer in which the forming material is an organic polymer material, the plasma formed by the mixture of helium gas and trifluoromethane can cause the curing action thereon, and the plasma formed by the mixture of oxygen and carbon tetrafluoride and the plasma formed by argon ions (Ar⁺) also cause the curing action thereon. Besides, the peeling of the photoresist layer which is cured in such case cannot be achieved very well by the ultrasonic treatment by using the developing solution and an organic solvent such as acetone, the ultrasonic treatment by using an alkaline solution such as sodium hydroxide, and the cleaning by using an oxide solution such as a solution containing oxygen ions.

It should be noted that the purpose of the curing treatment in the above step 102 is to cure the photoresist instead of etching the material to be etched. Therefore, the adopted plasma process may be different from that during the dry etching process to some extent. For example, the complexity, the input power and the reaction time of used devices, the control fineness, and the like all can be reduced to a certain extent to adapt to actual production application scenarios. With the curing treatment on the photoresist layer, the material to be etched may also interact with the plasma to generate the etching of a certain degree. On one hand, such etching occurs in the area to be etched, and on the other hand, the degree of such etching may be very tiny due to the factors such as the input power and the reaction time. Therefore, the phenomenon can be limited to a range that does not excessively affect the implementation of the etching method according to the present embodiment.

In the above step 103, the corresponding etching solution may be selected for etching according to the material to be etched. For example, hydrochloric acid is adopted as an etching solution to etch the metal material to be etched, hydrofluoric acid is adopted as an etching solution to etch the silicon dioxide material to be etched, and the like. The specific implementation manner can refer to the implementation process of the wet etching in various application scenarios, which is not described in detail here.

It can be seen that the plasma process commonly used for the dry etching is applied to the wet etching in the embodiment of the present disclosure. In turn, by using the defect that the photoresist is easily denatured after making contact with the plasma in the dry etching and thus difficult to be peeled off, the contact between the photoresist layer and the material to be etched is enhanced by using the plasma before the etching solution reacts with the material to be etched, thereby solving the problem of undercutting caused thereby, and favorably improving the product yield and product performances.

In addition, after the etching of the above step 103 is completed, the method may further comprise the process of removing the photoresist layer (the process is not shown in FIG. 1).

In step 104, the cured photoresist layer is subjected to ashing treatment by using the plasma capable of oxidizing the photoresist layer.

As an example, the cured photoresist layer may be oxidized by a oxygen plasma so as to be removed in the manner of ashing. Alternatively, the used plasma may be a gas obtained by mixing oxygen or air into argon gas, or a gas obtained by mixing oxygen or air into nitrogen gas, and may not be limited thereto. Compared with the manner of removal by the developing solution, the ultrasonic treatment by acetone, and the like, the above manner can completely remove the residual photoresist layer and avoid the damage to the surface covered by the photoresist layer, thereby achieving a better peeling effect.

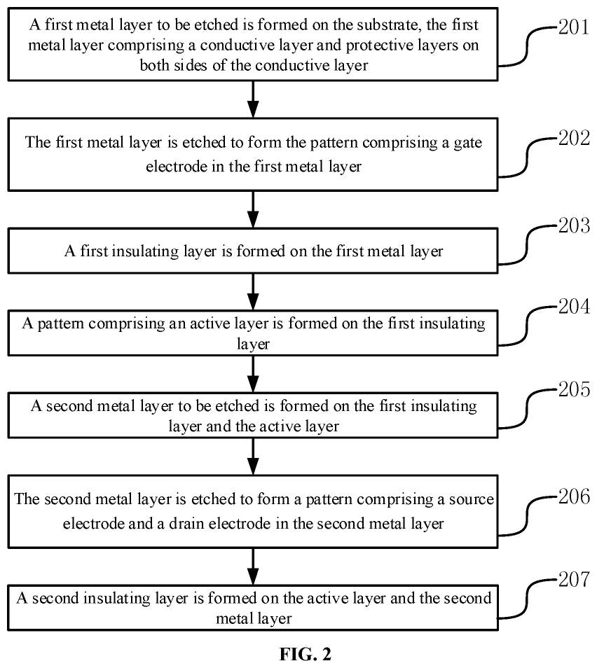

FIG. 2 is a flow chart of a method for manufacturing a thin film transistor according to an embodiment of the present disclosure. Referring to FIG. 2, the manufacturing method according to the present embodiment comprises the following steps.

In step 201, a first metal layer to be etched is formed on the substrate, the first metal layer comprising a conductive layer and protective layers on both sides of the conductive layer.

Herein, the substrate may be, for example, a glass substrate, a silicon wafer, and a substrate made of an organic polymer material such as polyimide, etc. The material forming the conductive layer in the first metal layer may be, for example, copper, aluminum, an alloy containing copper or an alloy containing aluminum or the like. The material for forming the protective layers in the first metal layer may be, for example, molybdenum, niobium, an alloy containing molybdenum or an alloy containing niobium or the like.

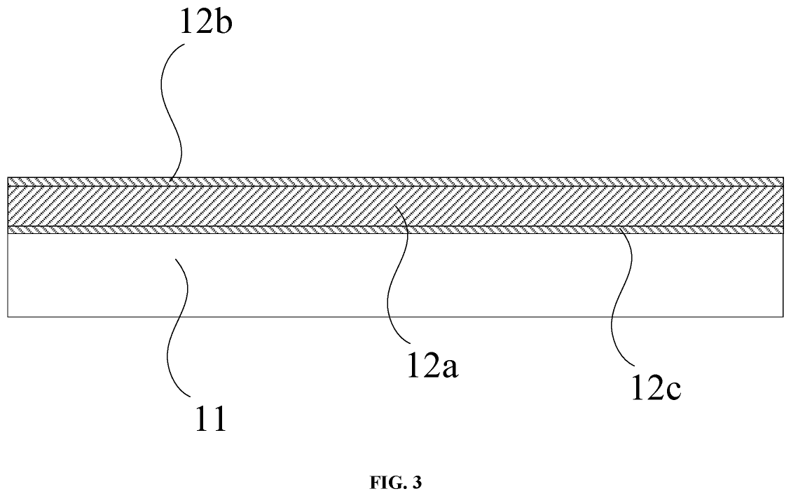

In one example, the structure formed by step 201 is as shown in FIG. 3. After the surface of the substrate 11 is cleaned and dried, a lower protective layer 12c, a conductive layer 12a and an upper protective layer 12b of the first metal layer can be sequentially deposited on the surface of the substrate 11 by adopting a physical vapor deposition (PVD) process which adopts metal materials. The setting of the parameters such as the thickness of each layer may be achieved by, for example, adjusting relevant process parameters.

In step 202, the first metal layer is etched to form the pattern comprising a gate electrode in the first metal layer.

Herein, the process of etching the first metal layer may adopt any of the above etching methods, and comprises a process of removing the photoresist layer after the etching is completed.

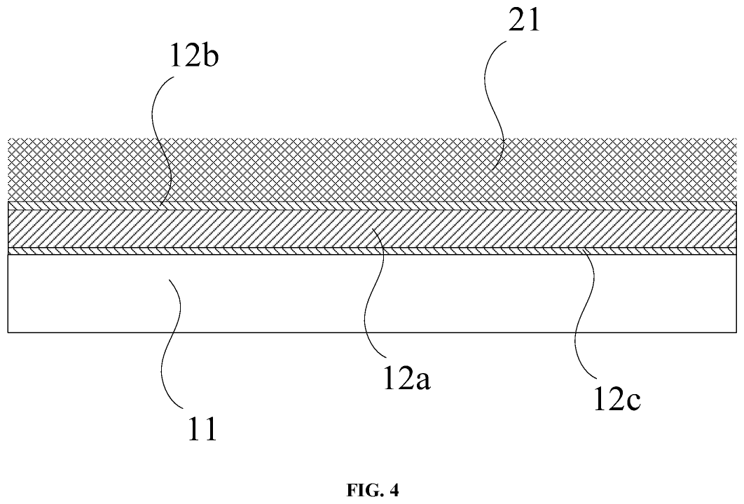

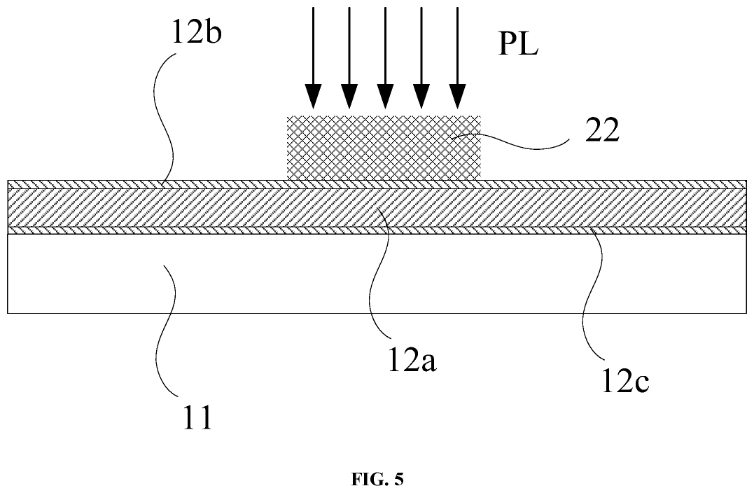

In an example, the specific process of the above step 101 may be performed in the following manner: firstly, on the basis of the structure shown in FIG. 3, a layer of photoresist 21 as shown in FIG. 4 is coated on the first metal layer by, for example, spin coating. The used photoresist may be, for example, positive photoresist. Next, all the photoresist 21 in the area to be etched may be irradiated with ultraviolet light through the mask to be fully exposed. Then the photoresist 21 in the area to be etched is placed in the developing solution to be completely removed by the developing process. The remaining photoresist 21 forms a photoresist layer 22 as shown in FIG. 5.

Following the previous example, the specific flow of the above step 102 can be performed in the following manner: based on the photoresist layer 22 shown in FIG. 5, by adopting a reactive ion etching (RIE) process, the mixture of oxygen and carbon tetrafluoride as a reactant is ionized to generate plasma, and the plasma is applied to the photoresist layer 21 until the curing treatment is completed. It should be noted that in all possible implementable application scenarios, various process parameters used in the procedure may refer to a known plasma treatment process capable of curing the photoresist. The process parameters may be adjusted by, for example, prior experimental calibrations and/or theoretical calculations to values which are appropriate for the application scenarios.

As an example of implementation, the above curing treatment may be implemented by using a device for dry etching. The specifically used photoresist is PR1-1000A-type positive photoresist. The volume ratio of the introduced carbon tetrafluoride to oxygen is 1200:1600. Meanwhile, the chamber pressure of the device is set to 10 mT (1.33 Pa). The power applied to an upper RF power source (Source Power) is set to 30 kW. The power applied to a lower power supply (Bias Power) is set to 30 kW. Under the above parameters, the curing treatment on the photoresist layer can be realized by means of the above dry etching device.

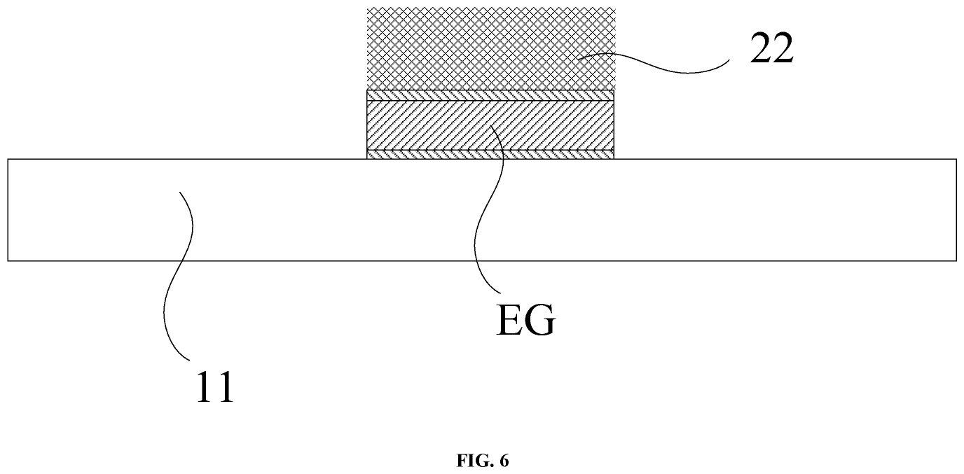

Following the previous example, the specific process of the above step 103 may be performed according to the following manner: using the cured photoresist layer 22 as a mask, using dilute hydrochloric acid as an etching solution, to etch the first metal layer (comprising the lower protective layer 12c, the conductive layer 12a, and the upper protective layer 12b) in the area to be etched, so that the remaining first metal layer forms a pattern comprising the gate electrode EG as shown in FIG. 6. It should be understood that since the photoresist layer 22 is subjected to the curing treatment, even though there exists the problem of poor adhesivity or small gaps between the photoresist layer 22 before the curing treatment and the upper surface of the first metal layer (i.e., the upper surface of the upper protective layer 12b), the cured photoresist layer 22 can still be better attached to the upper surface of the first metal layer, thereby helping to prevent the undercutting phenomenon caused by the permeation of the etching solution between the photoresist layer 22 and the first metal layer.

It should also be understood that the above curing treatment is essentially to increase a binding energy between the photoresist layer and the surface of the material to be etched (the minimum value of energy required to separate the two from each other). Therefore, based on such point, the change of the binding energy by the plasma process under relevant parameters such as different photoresist components, plasma components and process parameters may be pre-tested. Hence, the relevant parameters of the plasma treatment in different application scenarios can be selected according to the test result. Of course, the manner in which the relevant parameters are set may not be limited to the above manners.

Following to the previous example, the above manner of removing the photoresist layer may be performed in the following manner: on the basis of the structure shown in FIG. 6, the reactive ion etching (RIE) process is adopted to ionize the oxygen as a reactant to generate plasma, and the plasma reacts with the photoresist layer 21 until the ashing treatment is completed. Next, the ash-treated substrate can be cleaned by a liquid such as acetone or alcohol to completely remove the residual photoresist layer 21 and improve the cleanliness and flatness of each surface.

In step 203, a first insulating layer is formed on the first metal layer.

Herein, the first insulating layer may be formed by a material such as silicon oxide, silicon nitride, the photoresist and an organic polymer material, etc. And the first insulating layer may be manufactured by referring to the manufacturing manner for a gate insulating layer of the thin film transistor.

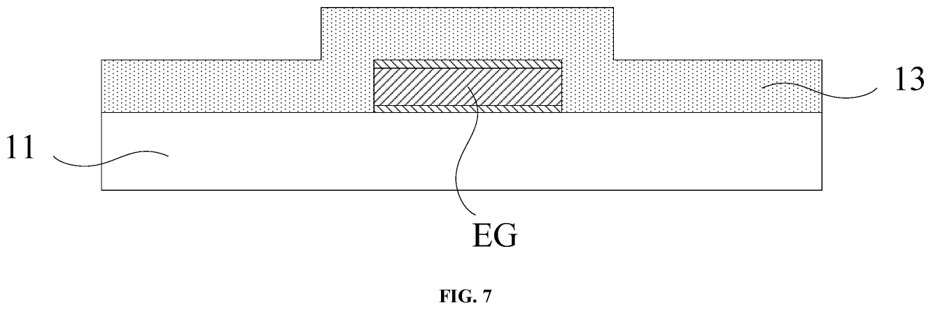

In one example, the structure formed by step 203 is as shown in FIG. 7. After the entire treatment of the above step 202 is completed, a first insulating layer 13 covering the substrate 11 and the first metal layer may be deposited on the substrate 11 and the first metal layer by a chemical vapor deposition (CVD) process. The thickness of the first insulating layer 13 may need to meet the relevant requirements on the thickness of the gate insulating layer of the thin film transistor. The setting of the parameters such as the thickness of the first insulating layer can be achieved by, for example, adjusting the relevant process parameters.

In step 204, a pattern comprising an active layer is formed on the first insulating layer.

Herein, the active layer may be formed by a semiconductor material such as amorphous silicon, polycrystalline silicon, single crystal silicon and a metal oxide semiconductor, and may be doped separately in different regions according to the required device structure. The implementation of the active layer may be specifically determined according to the type of the thin film transistor to be manufactured and the device parameters, which will not be described in detail here.

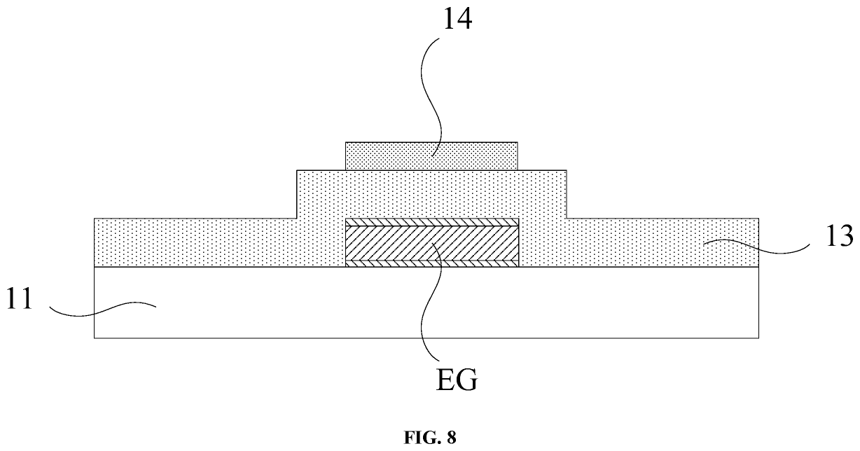

In one example, the structure formed by step 204 is as shown in FIG. 8. On the basis of the structure shown in FIG. 7, a semiconductor material layer may be formed by, for example, the chemical vapor deposition process. And then, an active layer 14 having the required doping condition and the required pattern is obtained by, for example, a doping process such as ion implantation and a patterning process. The active layer 14 overlaps with the above gate electrode EG.

In step 205, a second metal layer to be etched is formed on the first insulating layer and the active layer.

In step 206, the second metal layer is etched to form a pattern comprising a source electrode and a drain electrode in the second metal layer.

Herein, the forming material and the film layer composition of the second metal layer may be completely the same as the first metal layer, and any above etching method may be used when the second metal layer is etched.

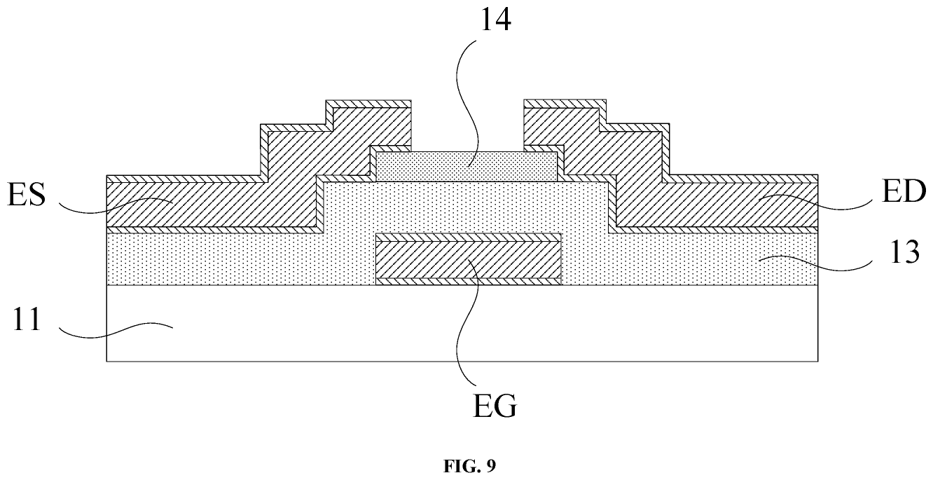

In one example, the structure formed through step 206 is as shown in FIG. 9. On the basis of the structure shown in FIG. 8, a lower protective layer, a conductive layer and an upper protective layer of the second metal layer may be sequentially deposited by the physical vapor deposition process which uses metal materials. Then the second metal layer is etched according to the process similar to above process for etching the first metal layer to form a pattern comprising a source electrode ES and a drain electrode ED as shown in FIG. 8. The source electrode ES and the drain electrode ED are respectively connected to the active layer 14 at different positions, so that it is possible to form a conductive channel that can be affected by a voltage on the gate electrode EG in the active layer 14 between the source electrode ES and the drain electrode ED.

In step 207, a second insulating layer is formed on the active layer and the second metal layer.

The second insulating layer may be formed by the material such as silicon oxide, silicon nitride, the photoresist and an organic polymer material, and may be manufactured by referring to the manufacturing manner for a passivation layer of the thin film transistor.

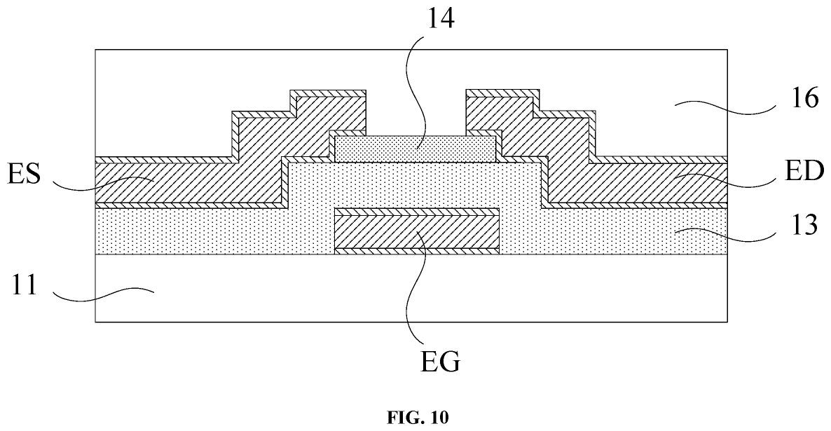

In one example, the structure formed by step 207 is as shown in FIG. 10. On the basis of the structure shown in FIG. 9, a second insulating layer 16 covering the substrate 11, the active layer 14 and the second metal layer may be deposited on the substrate 11, the active layer 14, and the second metal layer by the chemical vapor deposition (CVD) process. The parameters such as the thickness of the second insulating layer can be set by, for example, a means of adjusting the relevant process parameters. Thereby, the manufacturing of the basic structure of the thin film transistor is completed.

It should be understood that the manufacturing method according to the present embodiment may further comprise other processes not mentioned before step 201, after step 207 and at any one or more intermediate nodes between the different steps, to meet different application requirements in different application scenarios. For example, the method comprises manufacturing a device or an electrode connected to the thin film transistor after step 207, or manufacturing a layered structure disposed in the same layer as the second metal layer between step 206 and step 207, etc., which is not limited by the manufacturing method according to the present embodiment.

In addition, in an implementation manner of the present embodiment, the conductive layer of the first metal layer and/or the second metal layer is made of copper, and the protective layers of the first metal layer and/or the second metal layer are made of molybdenum-niobium alloy. Therefore, the gate electrode and/or the source and drain electrodes can have a smaller resistance value and lower-level signal delay due to the higher conductivity of copper. Due to the better stability of the molybdenum-niobium alloy, the effects of preventing atomic diffusion, preventing material oxidation, improving surface properties, improving contact resistance and the like can be achieved on both sides of the copper layer. Moreover, since the molybdenum-niobium alloy has certain problem of poor adhesivity to the photoresist, any above etching method can be used to solve the problem that the undercutting phenomenon easily occurs to the molybdenum-niobium alloy layer in the application scenarios.

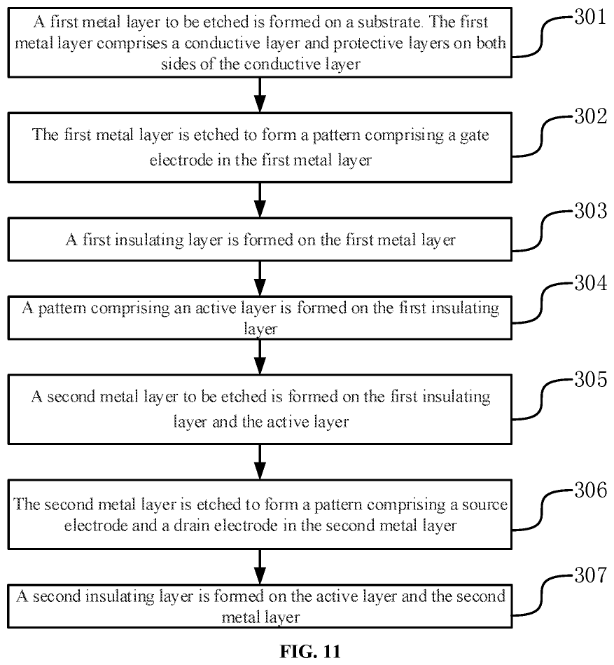

Based on the same invention concept, another embodiment of the present disclosure provides a manufacturing method of a thin film transistor. Referring to FIG. 11, the method includes the following steps.

In step 301, a first metal layer to be etched is formed on a substrate. The first metal layer comprises a conductive layer and protective layers on both sides of the conductive layer.

In step 302, the first metal layer is etched to form a pattern comprising a gate electrode in the first metal layer.

In step 303, a first insulating layer is formed on the first metal layer.

In step 304, a pattern comprising an active layer is formed on the first insulating layer.

In step 305, a second metal layer to be etched is formed on the first insulating layer and the active layer.

In step 306, the second metal layer is etched to forma pattern comprising a source electrode and a drain electrode in the second metal layer.

In step 307, a second insulating layer is formed on the active layer and the second metal layer.

Herein, the first metal layer and/or the second metal layer may be etched by any one of the above etching methods. In a possible implementation, the conductive layer is made of copper or a copper-containing alloy, and the protective layers are made of molybdenum or a molybdenum-containing alloy. It should be noted that, as the array substrate may be formed by thin film transistors arranged in an array and the difference between the thin film transistor and the array substrate may only lie in the pattern on each layer of structure, so that the process shown in FIG. 2 may also be considered as the manufacturing method of the array substrate in the present disclosure, and the related contents are not repeated herein.

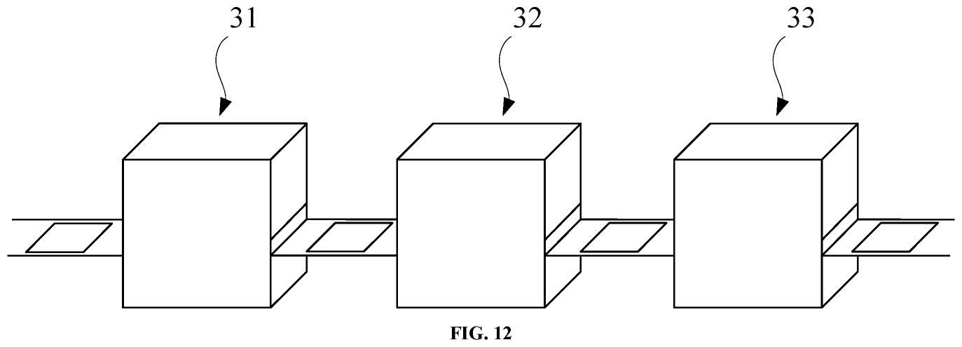

FIG. 12 is a schematic diagram of a structure of a process device according to an embodiment of the present disclosure. Referring to FIG. 12, the process device includes:

a first mechanism 31 configured to form a patterned photoresist layer on the surface of a material to be etched on a substrate, the patterned photoresist layer exposing an area to be etched on the surface of the material to be etched;

a second mechanism 32 connected to the first mechanism 31 and configured to receive the substrate processed by the first mechanism, and cure the photoresist layer by adopting a plasma process; and

a third mechanism 33 connected to the second mechanism 32 and configured to receive the substrate processed by the second mechanism 32 and to etch the material to be etched in the area to be etched by adopting an etching solution corresponding to the material to be etched.

In a possible implementation, the second mechanism is further configured to receive the substrate processed by the first mechanism and cure the photoresist layer by adopting a reactive ion etching process.

In a possible implementation, the material forming the photoresist layer is an organic polymer material, and the plasma used in the plasma process is generated by ionizing a mixture of carbon tetrafluoride and oxygen.

In a possible implementation, the process device further includes a fourth mechanism which is not shown in FIG. 12. The fourth mechanism is connected to the third mechanism 33 and configured to receive the substrate processed by the third mechanism 33, and perform ashing treatment on the cured photoresist layer by adopting plasma capable of oxidizing the photoresist layer.

In a possible implementation, the fourth mechanism is further configured to receive the substrate processed by the third mechanism, and perform ashing treatment on the cured photoresist layer by adopting a reactive ion etching process.

In a possible implementation, the material forming the photoresist layer is an organic polymer material, and the plasma capable of oxidizing the photoresist layer is generated by ionizing a mixture of carbon tetrafluoride and oxygen.

In one example, the above first mechanism 31 comprises a substrate cleaning device, a drying device, a photoresist coating device, an exposure device, and a developing device, which are sequentially disposed. The above second mechanism 32 comprises a dry etching process device and a microphotographic device. The above third mechanism 33 comprises a wet etching process device and a microphotographic device. The functions of the above fourth mechanism are realized by the second mechanism 32. In this way, the above etching method can be implemented in a streamline manner in accordance with, for example, the process shown in FIG. 2.

It should be understood that the specific exemplary manners for performing the operations by the above various mechanisms have been described in detail in the related method embodiments. The respective process or steps may be implemented by applying corresponding devices, which is not repeated in detail here.

It can be seen that the process device according to the embodiments of the present disclosure innovatively uses the plasma process commonly used for the dry etching to the wet etching, and in turn utilizes the defect that the photoresist in the dry etching is easily denatured after making contact with the plasma and thus difficult to peel. The plasma is used to enhance the contact between the photoresist layer and the material to be etched before the etching solution reacts with the material to be etched, thereby solving the problem of undercutting caused thereby and helping to improve the product yield and product performances.

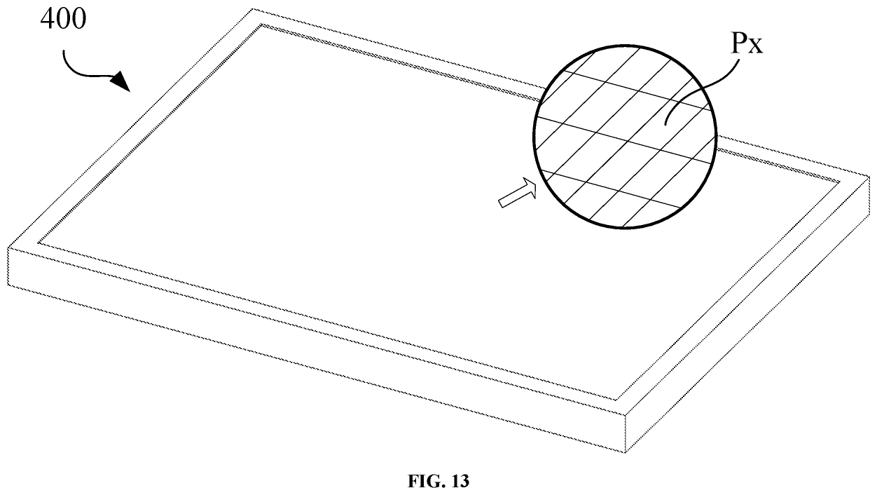

Based on the same inventive concept, the embodiment of the present disclosure provides a display device comprising the thin film transistor obtained by any of the above method for manufacturing a thin film transistor or the array substrate obtained by any above method for manufacturing an array substrate. The display device in the embodiment of the present disclosure may be any product or component with display function, such as a display panel, a mobile phone, a tablet computer, a television, a display, a notebook computer, a digital photo frame and a navigator. For example, the display device 400 shown in FIG. 13 comprises sub-pixel units Px disposed in rows and columns in the display area. The above thin film transistor may be disposed in the sub-pixel unit Px to implement adjustment on a display gray scale of the sub-pixel unit Px. The above array substrate may be disposed inside the display device 400. The array substrate may comprise at least one thin film transistor in each sub-pixel unit Px to implement the adjustment on the display gray scale of each sub-pixel unit Px.

It can be seen that the display device comprises any of the above thin film transistors or any of the above array substrates, and the gate electrode conductive layer and/or the source and drain conductive layers are etched by using any of the above etching methods in the manufacturing process of the thin film transistor and the array substrate. Therefore, the better product performances can be achieved based on the better etching result that can be achieved by the etching method.

The foregoing descriptions are merely embodiments of the present disclosure, and are not intended to limit the present disclosure. Within the spirit and principles of the disclosure, any modifications, equivalent substitutions, improvements, etc., are within the scope of protection of the present disclosure.

What is claimed is:

1. An etching method, comprising:
forming a patterned photoresist layer on a surface of a material to be etched, the patterned photoresist layer exposing an area to be etched on the surface of the material to be etched;
curing the photoresist layer by adopting a plasma process; and
etching the material to be etched by adopting an etching solution corresponding to the material to be etched.

2. The method according to claim 1, wherein curing the photoresist layer by adopting a plasma process comprises:
curing the photoresist layer by adopting a reactive ion etching process.

3. The method according to claim 1, wherein the material forming the photoresist layer is an organic polymer material, and the plasma used in the plasma process is generated by ionizing a mixture of carbon tetrafluoride and oxygen.

4. The method according to claim 1, wherein the material forming the photoresist layer is a positive photoresist of type PR1-1000A, and the plasma used in the plasma process is generated by ionizing a mixture of carbon tetrafluoride and oxygen.

5. The method according to claim 1, after etching the material to be etched by adopting an etching solution corresponding to the material to be etched, the method further comprises:
performing ashing treatment on the cured photoresist layer by adopting plasma capable of oxidizing the photoresist layer.

6. The method according to claim 5, wherein performing ashing treatment on the cured photoresist layer by adopting plasma capable of oxidizing the photoresist layer comprises:
performing the ashing treatment on the photoresist layer by adopting a reactive ion etching process.

7. The method according to claim 5, wherein the material forming the photoresist layer is an organic polymer material, and the plasma capable of oxidizing the photoresist layer is generated by ionizing a mixture of carbon tetrafluoride and oxygen.

8. A manufacturing method of a thin film transistor, comprising:
forming a first metal layer to be etched on a substrate, the first metal layer comprising a conductive layer and protective layers on both sides of the conductive layer; and
forming a patterned photoresist layer on the surface of the first metal layer, the patterned photoresist layer exposing an area to be etched on the surface of the first metal layer;
curing the photoresist layer by adopting a plasma process; and
etching the first metal layer by adopting an etching solution corresponding to the first metal layer to form a pattern comprising a gate electrode in the first metal layer.

9. The manufacturing method according to claim 8, further comprising:
forming a first insulating layer on the first metal layer;
forming a pattern comprising an active layer on the first insulating layer;
forming a second metal layer to be etched on the first insulating layer and the active layer;
forming a patterned photoresist layer on the surface of the second metal layer, the patterned photoresist layer exposing an area to be etched on the surface of the second metal layer;
curing the photoresist layer formed on the surface of the second metal layer by adopting a plasma process; and
etching the second metal layer by adopting an etching solution corresponding to the second metal layer to form a pattern comprising a source electrode and a drain electrode in the second metal layer; and
forming a second insulating layer on the active layer and the second metal layer.

10. The manufacturing method according to claim 8, wherein the conductive layer is made of any one of copper and a copper-containing alloy, and the protective layers are made of any one of molybdenum and a molybdenum-containing alloy.

11. A process device comprising:
a first mechanism configured to form a patterned photoresist layer on the surface of a material to be etched on a substrate, the patterned photoresist layer exposing an area to be etched on the surface of the material to be etched;
a second mechanism configured to receive the substrate processed by the first mechanism, and cure the photoresist layer by adopting a plasma process; and
a third mechanism configured to receive the substrate processed by the second mechanism and to etch the material to be etched in the area to be etched by adopting an etching solution corresponding to the material to be etched.

12. The process device according to claim 11, wherein the second mechanism is further configured to receive the substrate processed by the first mechanism and cure the photoresist layer by adopting a reactive ion etching process.

13. The process device according to claim 11, wherein a material forming the photoresist layer is an organic high polymer material, and plasma used in the plasma process is generated by ionizing a mixture of carbon tetrafluoride and oxygen.

14. The process device according to claim 11, further comprising:
a fourth mechanism configured to receive the substrate processed by the third mechanism, and perform ashing treatment on the cured photoresist layer by adopting plasma capable of oxidizing the photoresist layer.

15. The process device according to claim 14, wherein the fourth mechanism is further configured to receive the substrate processed by the third mechanism, and perform ashing treatment on the cured photoresist layer by adopting a reactive ion etching process.

16. The process device according to claim 14, wherein a material forming the photoresist layer is an organic high polymer material, and the plasma capable of oxidizing the photoresist layer is generated by ionizing a mixture of carbon tetrafluoride and oxygen.

17. A display device, comprising a thin film transistor obtained by the manufacturing method according to claim 8.

18. The manufacturing method according to claim 9, wherein the conductive layer is made of any one of copper and a copper-containing alloy, and the protective layers are made of any one of molybdenum and a molybdenum-containing alloy.

19. The manufacturing method according to claim 8, wherein curing the photoresist layer by adopting a plasma process comprises:
curing the photoresist layer by adopting a reactive plasma etching process.

20. The manufacturing method according to claim 8, wherein after etching the first metal layer by adopting an etching solution corresponding to the first metal layer, the method further comprises:
performing asking treatment on the cured photoresist layer by adopting plasma capable of oxidizing the photoresist layer.
